(19) United States
(12) Patent Application Publication
(10) Pub. No.: US 2025/0284196 A1
(43) Pub. Date: Sep. 11, 2025

(54) RESIST TOPCOAT COMPOSITIONS AND METHODS OF FORMING PATTERNS USING THE COMPOSITION

(71) Applicant: SAMSUNG SDI CO., LTD., Yongin-si (KR)

(72) Inventors: Ran NAMGUNG, Suwon-si (KR); Kyoungjin HA, Suwon-si (KR); Hyeon PARK, Suwon-si (KR); Daeseok SONG, Suwon-si (KR)

(21) Appl. No.: 18/982,988

(22) Filed: Dec. 16, 2024

(30) Foreign Application Priority Data
Mar. 11, 2024 (KR) 10-2024-0034112

(51) Int. Cl. G03F 7/095; C09D 133/14; G03F 7/00; G03F 7/16; H01L 21/027

(52) U.S. Cl. CPC G03F 7/0955; C09D 133/14; G03F 7/168; G03F 7/70033; H01L 21/0271

(57) ABSTRACT

Provided are a resist topcoat composition and a method of forming patterns using the resist topcoat composition, the resist topcoat composition including a copolymer including a first structural unit represented by Chemical Formula M-1 and a second structural unit represented by Chemical Formula M-2; a photoacid generator; and a solvent, wherein the photoacid generator is a non-ionic compound or an ionic compound, the non-ionic compound includes an organic sulfonate group, the ionic compound includes at least one selected from a conjugate base of an inorganic acid and a conjugate base of an organic sulfonic acid as an anion.

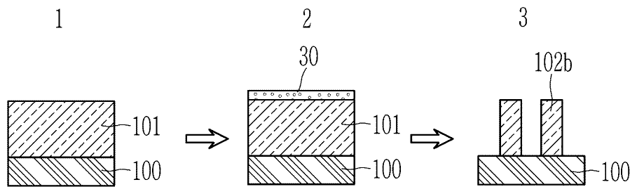

### CROSS-REFERENCE TO RELATED APPLICATION

The present application claims priority to and the benefit of Korean Patent Application No. 10-2024-0034112, filed on Mar. 11, 2024, in the Korean Intellectual Property Office, the entire content of which is hereby incorporated by reference.

### BACKGROUND

### 1. Field

Embodiments of this disclosure relate to a resist topcoat composition and a method of forming a pattern using the same.

### 2. Description of the Related Art

Recently, the semiconductor industry has been developing an ultrafine technique having a pattern of several to several tens nanometer size. Such ultrafine techniques benefit from effective photolithographic processes.

Photolithographic processes generally involve providing a material layer on a semiconductor substrate, coating a photoresist layer thereon, exposing and developing to form a photoresist pattern, and then etching the material layer using the photoresist pattern as a mask.

As photolithography processes develop, a degree of pattern integration is increasing, and materials and technologies for addressing various problems occurring in these processes are being researched.

For example, if EUV is irradiated to the photoresist, because there may be a region where a large amount of light or a small amount of light is randomly irradiated due to large energy per photon, which is a photo shot noise, and/or an EUV absorption difference between top and bottom of the photoresist may cause pattern distribution deterioration such as roughness (for example, LER: line edge roughness, and/or LWR: line width roughness) or IPU (in-point uniformity) of the patterns, in order to improve this pattern distribution deterioration, technology development is being researched.

### SUMMARY

Some embodiments of the present disclosure provide a resist topcoat composition capable of reducing pattern distribution by preventing or reducing pattern deterioration.

Some embodiments provide a method of forming patterns using the resist topcoat composition.

Some embodiments provide a resist topcoat composition including a copolymer including a first structural unit represented by Chemical Formula M-1 and a second structural unit represented by Chemical Formula M-2; a photoacid generator; and a solvent, wherein the photoacid generator is a non-ionic compound or an ionic compound, the non-ionic compound includes an organic sulfonate group, the ionic compound includes at least one selected from a conjugate base of an inorganic acid and a conjugate base of an organic sulfonic acid as an anion.

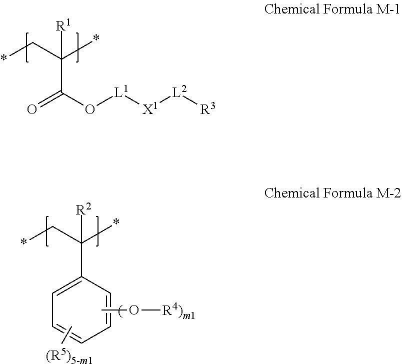

In Chemical Formula M-1 and Chemical Formula M-2,
R¹ and R² are each independently hydrogen or a substituted or unsubstituted C1 to C10 alkyl group,
L¹ and L² are each independently a single bond (e.g., a single covalent bond), a substituted or unsubstituted C1 to C10 alkylene group, or a combination thereof,
X¹ is a single bond (e.g., a single covalent bond), —O—, —S—, —S(O)—, —S(O)₂—, —C(O)—, —(CO)O—, —O(CO), —O(CO)O—, —NR^{a}— (wherein, R^{a} is hydrogen, deuterium, or a substituted or unsubstituted C1 to C10 alkyl group), or a combination thereof,
R³ is hydrogen, fluorine, a hydroxy group, a substituted or unsubstituted C1 to C20 alkyl group, or a combination thereof,
R⁴ is hydrogen, or C(═O)R^{b},
R^{b} is a substituted or unsubstituted C1 to C10 alkyl group,
at least one selected from R³, L¹, and L² includes fluorine and a hydroxy group,
R⁵ is hydrogen, a halogen, a hydroxy group, a substituted or unsubstituted C1 to C10 alkyl group, or a combination thereof,
m1 is one of the integers from 1 to 4, and
* is a linking point.

Some embodiments provide a method of forming patterns which includes coating and heating a photoresist composition on a substrate to form a photoresist layer, coating and heating the aforementioned resist topcoat composition on the photoresist layer to form a topcoat, and exposing and developing the topcoat and the photoresist layer to form a resist pattern.

If the resist topcoat composition according to some embodiments is applied to a photoresist for EUV, an amount of acid generated in the exposed region is increased, enabling patterning with less energy (e.g., reducing an amount of energy utilized to form a pattern), thereby improving sensitivity of the EUV photoresist.

### BRIEF DESCRIPTION OF THE DRAWING

The accompanying drawing, together with the specification, illustrates embodiments of the subject matter of the present disclosure, and, together with the description, serves to explain principles of embodiments of the subject matter of the present disclosure.

The accompanying drawing is a schematic view illustrating a method of forming patterns using a resist topcoat composition according to some embodiments.

### DETAILED DESCRIPTION

Hereinafter, embodiments will be described in more detail so that those skilled in the art can easily implement the subject matter of the present disclosure. However, the subject matter of this disclosure may be embodied in many different forms and should not be construed as limited to the example embodiments set forth herein.

In the drawing, the thickness of layers, films, panels, regions, etc., may be exaggerated for clarity and like reference numerals designate like elements throughout the specification. It will be understood that if an element such as a layer, film, region, or substrate is referred to as being “on” another element, it can be directly on the other element or intervening elements may also be present. In contrast, if an element is referred to as being “directly on” another element, there are no intervening elements present.

As used herein, if a definition is not otherwise provided, “substituted” refers to replacement of a hydrogen atom of a compound by a substituent selected from a halogen atom (F, Br, Cl, or I), an oxo group, a hydroxy group, a thiol group, a nitro group, a cyano group, an amino group, an azido group, an amidino group, a hydrazino group, a hydrazono group, a carbonyl group, a carbamyl group, a thiol group, an ester group, a carboxyl group or a salt thereof, a sulfonic acid group or a salt thereof, a phosphoric acid group or a salt thereof, a vinyl group, a C1 to C20 alkyl group, a C2 to C20 alkenyl group, a C2 to C20 alkynyl group, a C6 to C30 aryl group, a C7 to C30 arylalkyl group, a C6 to C30 allyl group, a C1 to C30 alkoxy group, a C1 to C30 sulfide group, a C1 to C20 heteroalkyl group, a C2 to C20 heteroaryl group, a C3 to C20 heteroarylalkyl group, a C3 to C30 cycloalkyl group, a C3 to C15 cycloalkenyl group, a C6 to C15 cycloalkynyl group, a C3 to C30 heterocycloalkyl group, and a combination thereof.

As used herein, if a definition is not otherwise provided, “alkyl group” refers to a linear or branched aliphatic hydrocarbon group. The alkyl group may be “saturated alkyl group” without any double bond or triple bond.

The alkyl group may be a C1 to C8 alkyl group. In embodiments, the alkyl group may be a C1 to C10 alkyl group or a C1 to C6 alkyl group. For example, the C1 to C5 alkyl group means that the alkyl chain includes 1 to 5 carbon atoms and is selected from, for example, methyl, ethyl, propyl, iso-propyl, n-butyl, iso-butyl, sec-butyl, and tert-butyl.

The alkyl group refers to examples that include, for example, a methyl group, an ethyl group, a propyl group, an isopropyl group, a butyl group, an isobutyl group, a tert-butyl group, a pentyl group, a hexyl group, and the like.

In chemical formulas described herein, t-Bu refers to a tert-butyl group.

As used herein, if a definition is not otherwise provided, “cycloalkyl group” refers to a monovalent cyclic aliphatic hydrocarbon group.

The cycloalkyl group refers to examples that include, for example, a cyclopropyl group, a cyclobutyl group, a cyclopentyl group, a cyclohexyl group, and the like.

The cycloalkyl group may be a C3 to C10 cycloalkyl group, for example, a C3 to C8 cycloalkyl group, a C3 to C7 cycloalkyl group, or a C3 to C6 cycloalkyl group. For example, the cycloalkyl group may be a cyclopropyl group, a cyclobutyl group, a cyclopentyl group, or a cyclohexyl group, but is not limited thereto.

As used herein, unless otherwise defined, “alkenyl group” refers to an aliphatic unsaturated alkenyl group including at least one double bond as a linear or branched aliphatic hydrocarbon group.

As used herein, unless otherwise defined, “alkynyl group” refers to an aliphatic unsaturated alkynyl group including at least one triple bond as a linear or branched aliphatic hydrocarbon group.

As used herein, “aryl group” refers to a substituent in which all atoms in the cyclic substituent have a p-orbital and these p-orbitals are conjugated and may include a monocyclic, polycyclic or fused ring (e.g., rings sharing adjacent pairs of carbon atoms) functional groups.

As used herein, if a definition is not otherwise provided, “hetero” refers to one including 1 to 3 heteroatoms selected from N, O, S, Se, and P.

In the present disclosure, if a definition is not otherwise provided, “heterocycloalkyl group” refers to a cycloalkyl group containing at least one hetero atom selected from N, O, S, P, and Si.

In embodiments of the present disclosure, “heteroaryl group” refers to an aryl group including at least one hetero atom selected from N, O, S, P, and Si. Two or more heteroaryl groups are linked by a sigma bond directly, or if the heteroaryl group includes two or more rings, the two or more rings may be fused together. If the heteroaryl group is a fused ring, each ring may include 1 to 3 hetero atoms.

In embodiments, in this specification, acrylic polymer refers to acrylic polymer and/or methacrylic polymer.

Unless otherwise specified in the present specification, the weight average molecular weight is measured by dissolving a powder sample in tetrahydrofuran (THF) and then using 1200 series Gel Permeation Chromatography (GPC) of Agilent Technologies (column is Shodex Company LF-804, standard sample is Shodex company polystyrene).

In embodiments, unless otherwise defined in the specification, “*” indicates a linking point of a structural unit or a compound moiety of a compound.

Hereinafter, a resist topcoat composition according to some embodiments is described.

Embodiments of the present disclosure relate to a photoresist topcoat composition that can improve sensitivity of the photoresist by maximizing or increasing the amount of acid generated in the exposed region during the fine pattern formation process of photolithography using high-energy rays such as EUV (extreme ultraviolet; wavelength 13.5 nm), and a method of forming a photoresist pattern using such as a topcoat.

A resist topcoat composition according to some embodiments includes a copolymer including a first structural unit represented by Chemical Formula M-1 and a second structural unit represented by Chemical Formula M-2; a photoacid generator; and a solvent, wherein the photoacid generator is a non-ionic compound or an ionic compound, the non-ionic compound includes an organic sulfonate group, the ionic compound includes at least one selected from a conjugate base of an inorganic acid and a conjugate base of an organic sulfonic acid as an anion.

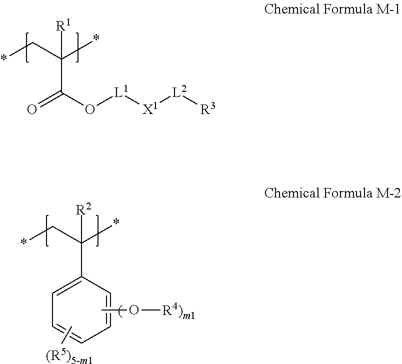

In Chemical Formula M-1 and Chemical Formula M-2,
R¹ and R² are each independently hydrogen or a substituted or unsubstituted C1 to C10 alkyl group,
L¹ and L² are each independently a single bond (e.g., a single covalent bond), a substituted or unsubstituted C1 to C10 alkylene group, or a combination thereof,
X¹ is a single bond (e.g., a single covalent bond), —O—, —S—, —S(O)—, —S(O)₂—, —C(O)—, —(CO)O—, —O(CO), —O(CO)O—, —NR^{a}— (wherein, R^{a} is hydrogen, deuterium, or a substituted or unsubstituted C1 to C10 alkyl group), or a combination thereof,
R³ is hydrogen, fluorine, a hydroxy group, a substituted or unsubstituted C1 to C20 alkyl group, or a combination thereof,
R⁴ is hydrogen, or C(═O)R^{b},
R^{b} is a substituted or unsubstituted C1 to C10 alkyl group,
at least one selected from R³, L¹, and L² includes fluorine and a hydroxy group,
R⁵ is hydrogen, a halogen, a hydroxy group, a substituted or unsubstituted C1 to C10 alkyl group, or a combination thereof,
m1 is one of the integers from 1 to 4, and
* is a linking point. As used herein, the term “fluorine” may refer to a fluorine atom.

The photoresist topcoat composition according to some embodiments includes a photoacid generator and can be coated on the photoresist layer to maximize or increase the amount of acid generated during exposure, thereby increasing the sensitivity of the photoresist.

A photoacid generator is a compound that generates an acid compound upon light irradiation. Examples of the acid generated according to embodiments of the present disclosure include hydrogen halide, sulfonic acid, an antimony derivative, and halogen peroxide.

In embodiments, a use of the photoacid generator can increase an amount of acid generated in the exposed region by exposure on the upper portion of the photoresist layer. Accordingly, by increasing the EUV absorption rate, patterning is possible with less energy (e.g., the patterning may be performed utilizing relatively less energy), thereby improving sensitivity.

The first structural unit included in the copolymer of the composition has characteristics of having almost no reactivity with the photoresist but being well dissolved in a solvent and thus may protect the photoresist, while minimizing or increasing an influence on the photoresist, and the second structural unit may increase EUV absorption to improve sensitivity.

Accordingly, the copolymer may have excellent solubility in solvents, be uniformly (e.g., substantially uniformly) coated on a pattern, and minimize or reduce the effect on the resist.

As an example, the copolymer may include the first structural unit represented by Chemical Formula M-1 and the second structural unit represented by Chemical Formula M-2.

In Chemical Formula M-2, if m1 is 2 or more, each O—R⁴ may be the same or different from each other.

In Chemical Formula M-2, if 5-m1 is 2 or more, each R⁵ may be the same or different from each other.

The meaning that at least one selected from R³, L¹, and L² includes a fluorine and hydroxy group may include embodiments where,
R³ may be a C1 to C20 alkyl group substituted with at least one fluorine and at least one hydroxy group, or
at least one selected from L¹ and L² may be a C1 to C10 alkylene group substituted with one or more fluorine and one or more hydroxy groups, or
at least one selected from L¹ and L² may be a C1 to C10 alkylene group substituted with one or more fluorine, and at least one of the others may be a C1 to C10 alkylene group substituted with one or more hydroxy groups, or
R³ may be fluorine, and at least one selected from L¹ and L² may be a C1 to C10 alkylene group substituted with one or more hydroxy groups, or
R³ may be a hydroxy group, and at least one selected from L¹ and L² may be a C1 to C10 alkylene group substituted with one or more fluorine, or
R³ may be a C1 to C10 alkyl group substituted with one or more fluorine and one or more hydroxy groups, or
R³ may be a C1 to C10 alkyl group substituted with one or more hydroxy groups and one or more C1 to C10 fluoroalkyl groups.

As an example, the first structural unit may be represented by Chemical Formula 1.

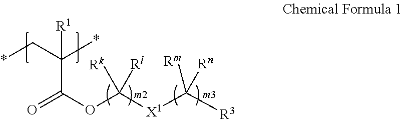

In Chemical Formula 1,
R¹ is hydrogen or a substituted or unsubstituted C1 to C10 alkyl group,
R^{k}, R^{l}, R^{m}, Rⁿ, and R³ are each independently hydrogen, fluorine, a hydroxy group, a substituted or unsubstituted C1 to C20 alkyl group, or a combination thereof,
m2 and m3 are each independently an integer from 1 to 10,
X¹ is a single bond (e.g., a single covalent bond), —O—, —S—, —S(O)—, —S(O)₂—, —C(O)—, —(CO)O—, —O(CO), —O(CO)O—, —NR^{a}— (wherein, R^{a} is hydrogen, deuterium, or a substituted or unsubstituted C1 to C10 alkyl group), or a combination thereof, and
at least one selected from R^{k}, R^{l}, R^{m}, Rⁿ, and R³ includes fluorine and a hydroxy group.

In Chemical Formula 1, if m2 is 2 or more, each R^{k} may be the same or different from each other.

In Chemical Formula 1, if m2 is 2 or more, each R^{l} may be the same or different from each other.

In Chemical Formula 1, if m3 is 2 or more, each R^{m} may be the same or different from each other.

In Chemical Formula 1, if m3 is 2 or more, each Rⁿ may be the same or different from each other.

The meaning that at least one selected from R^{k}, R^{l}, R^{m}, Rⁿ, and R³ includes a fluorine and hydroxy group may include embodiments where:
at least one selected from R^{k}, R^{l}, R^{m}, Rⁿ, and R³ is each independently a fluorine and hydroxy group, or
at least one selected from R^{k}, R^{l}, R^{m}, Rⁿ, and R³ each independently includes a C1 to C10 alkyl group substituted with one or more fluorine and a C1 to C10 alkyl group substituted with one or more hydroxy groups, or
at least one selected from R^{k}, R^{l}, R^{m}, Rⁿ, and R³ each independently includes one or more hydroxy groups and one or more C1 to C10 alkyl groups substituted with fluorine, or
at least one selected from R^{k}, R^{l}, R^{m}, Rⁿ, and R³ each independently includes a C1 to C5 alkyl group substituted with one or more hydroxy groups and one or more C1 to C5 fluoroalkyl groups, or
at least one selected from R^{k}, R^{l}, R^{m}, Rⁿ, and R³ is fluorine, and at least one of the others is a hydroxy group, or
at least one selected from R^{k}, R^{l}, R^{m}, Rⁿ, and R³ is fluorine, and at least one of the others includes a C1 to C10 alkyl group substituted with one or more hydroxy groups, or
at least one selected from R^{k}, R^{l}, R^{m}, Rⁿ, and R³ is a hydroxy group, and at least one of the others includes a C1 to C10 alkyl group substituted with one or more fluorine, or
at least one selected from R^{k}, R^{l}, R^{m}, Rⁿ, and R³ is a C1 to C20 alkyl group substituted with one or more fluorine, and at least one of the others is a C1 to C20 alkyl group substituted with one or more hydroxy groups.

For example, R¹ may be hydrogen or a methyl group,
X¹ may be a single bond (e.g., a single covalent bond), —O—, or —NR^{a}— (wherein, R^{a} is hydrogen, deuterium, or a substituted or unsubstituted C1 to C10 alkyl group), and
R³ may be fluorine, a hydroxy group, a C1 to C10 alkyl group substituted with at least one fluorine, or a C1 to C10 alkyl group substituted with at least one hydroxy group.

As an example, in Chemical Formula 1, at least one selected from R^{m}, Rⁿ, and R³ may include a fluorine and a hydroxy group.

As an example, in Chemical Formula 1, at least one selected from R^{m} and Rⁿ may be fluorine or a C1 to C10 alkyl group substituted with at least one fluorine, and R⁵ may be a hydroxy group or a C1 to C10 alkyl group substituted with at least one hydroxy group.

As an example, in Chemical Formula 1, at least one selected from R^{m} and Rⁿ may be a hydroxy group or a C1 to C10 alkyl group substituted with at least one hydroxy group, and R³ may be fluorine or a C1 to C10 alkyl group substituted with at least one fluorine.

As an example, in Chemical Formula 1, R^{m} may be a hydroxy group or a C1 to C10 alkyl group substituted with at least one hydroxy group, Rⁿ may be fluorine or a C1 to C10 alkyl group substituted with at least one fluorine, and R³ may be a hydroxy group, fluorine, or a C1 to C10 alkyl group substituted with at least one selected from fluorine and hydroxy groups.

As an example, in Chemical Formula 1, at least one selected from R^{m} and Rⁿ may be fluorine or a C1 to C10 alkyl group substituted with at least one fluorine, and R³ may be a hydroxy group or a C1 to C5 alkyl group substituted with at least one selected from a hydroxy group and a C1 to C5 fluoroalkyl group.

For example, the first structural unit may be selected from Group I.

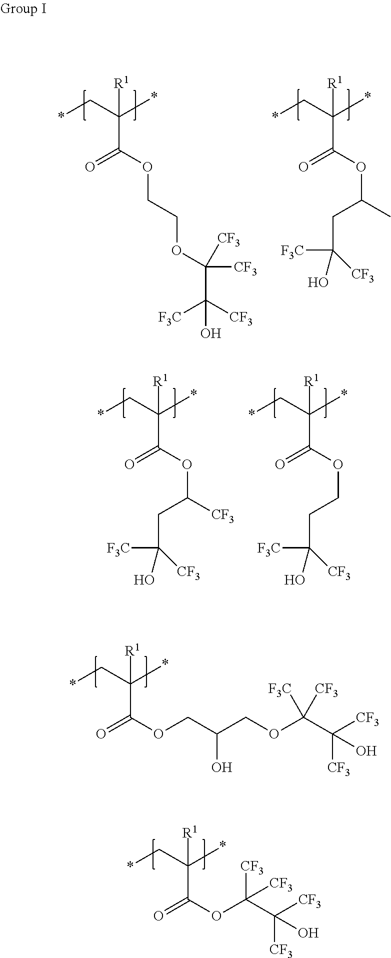

In Group I,
R¹ is each independently hydrogen or a methyl group and * is a linking point.

As an example, the second structural unit may be represented by any one selected from Chemical Formula 2-1 to Chemical Formula 2-4.

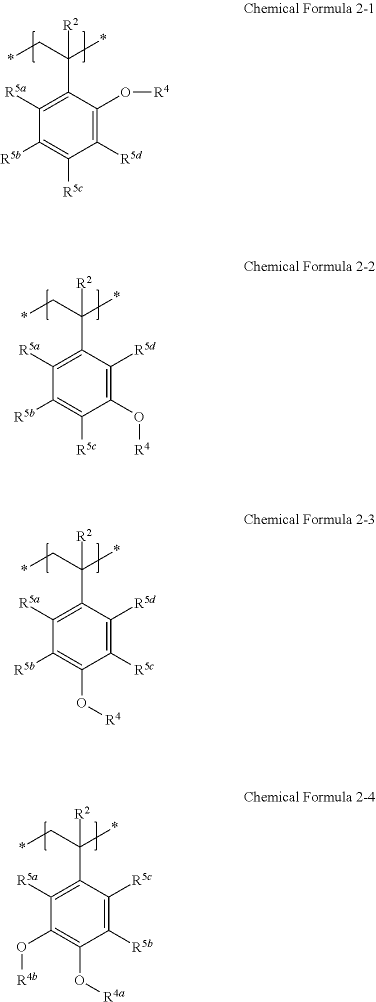

In Chemical Formula 2-1 to Chemical Formula 2-4,
R² is hydrogen or a methyl group,
R⁴, R^{4a}, and R^{4b} are each independently hydrogen or C(═O)R^{b},
R^{b} is a substituted or unsubstituted C1 to C5 alkyl group,
R^{5a}, R^{5b}, R^{5c}, and R^{5d} are each independently hydrogen, halogen, a hydroxy group, a substituted or unsubstituted C1 to C10 alkyl group, or a combination thereof, and
* is a linking point.

As an example, at least one R⁵ may be a halogen.

As an example, at least one R⁵ may be an iodine group.

If the second structural unit includes an iodine group, sensitivity may be further improved.

For example, the second structural unit may be selected from Group Il.

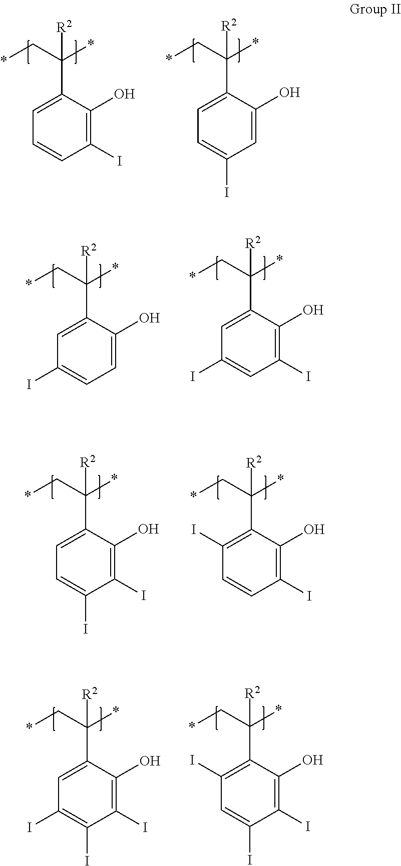

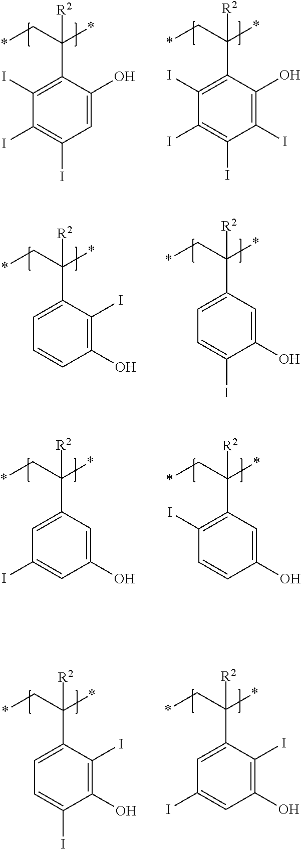

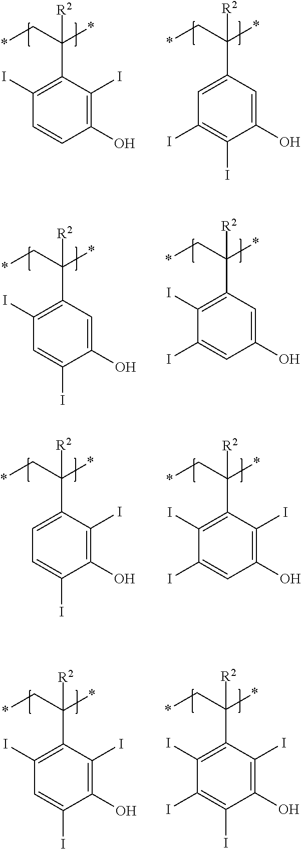

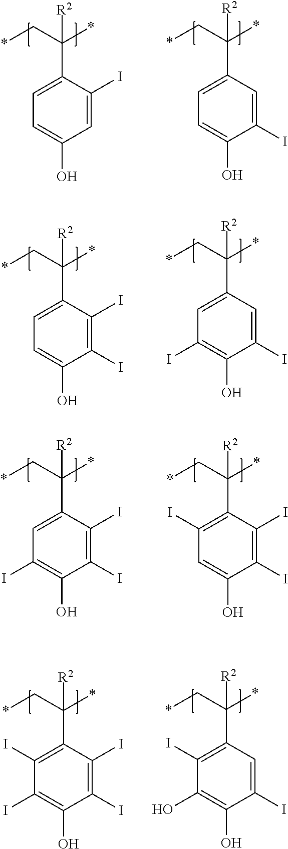

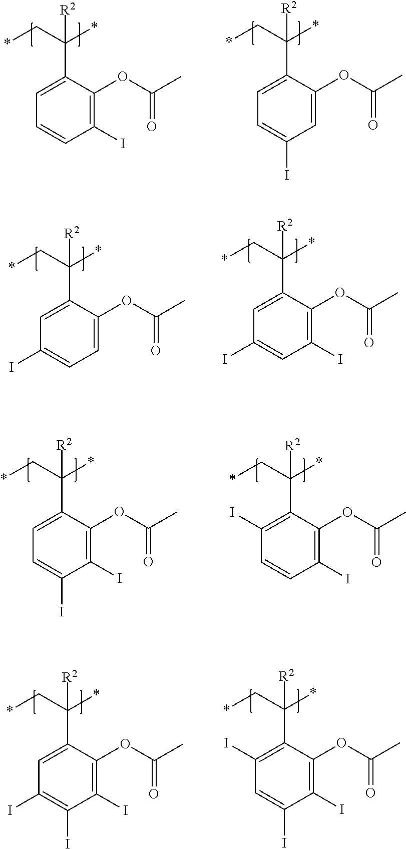

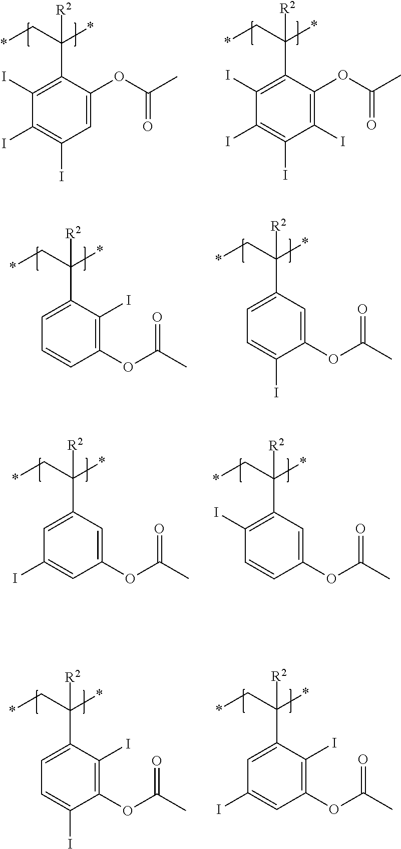

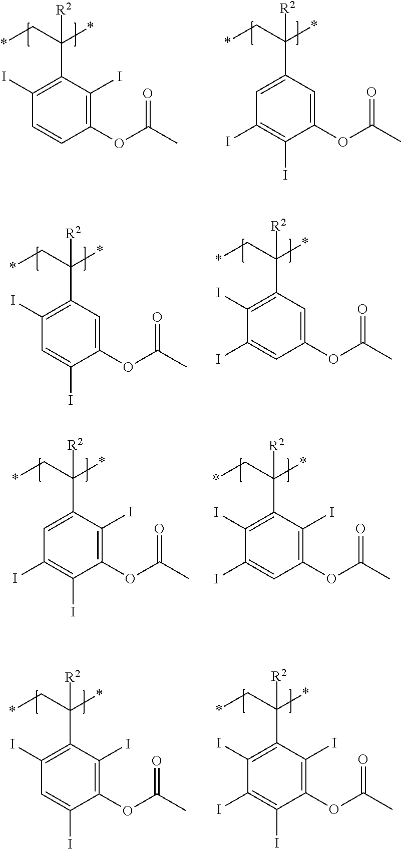

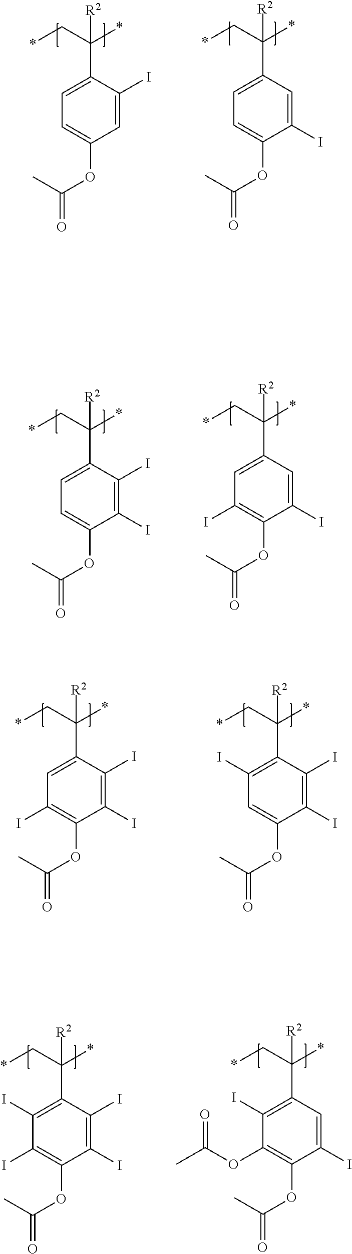

In Group II,
R² is each independently hydrogen or a methyl group and * is a linking point.

The copolymer may include about 50 to about 99 mol % of the first structural unit, about 1 to about 50 mol % of the second structural unit, and about 1 to about 40 mol % of the third structural unit (e.g., based on 100 mol % of the copolymer).

For example, the copolymer may include about 70 to about 99 mol % of the first structural unit, about 1 to about 30 mol % of the second structural unit, most specifically about 80 to about 95 mol % of the first structural unit, and about 5 to about 20 mol % of the second structural unit.

If the mole ratio of each structural unit included in the copolymer is within the above ranges, the solubility in organic solvents is improved and the pattern can be uniformly (e.g., substantially uniformly) coated.

The copolymer may have a weight average molecular weight (Mw) of about 1,000 g/mol to about 50,000 g/mol. For example, it may have a weight average molecular weight of about 2,000 g/mol to about 30,000 g/mol, for example, about 3,000 g/mol to about 20,000 g/mol, or for example about 4,000 g/mol to about 10,000 g/mol, but is not limited thereto. If the weight average molecular weight of the copolymer is within the above ranges, a carbon content and solubility in a solvent of the resist topcoat composition including the copolymer may be optimized or improved.

The copolymer may be included in an amount of about 0.1 wt % to about 10 wt % based on a total weight of the resist topcoat composition. Within the above range, the resist topcoat may be easily removed.

In some embodiments, the copolymer may be selected from those listed in Group III.

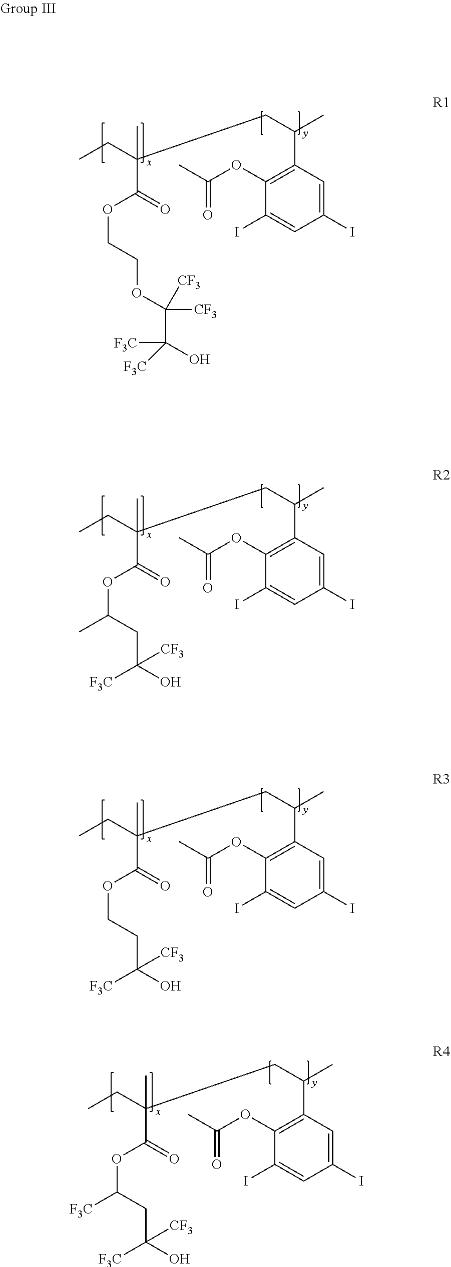

In Group III, x:y may be about 99:1 to about 90:10, and for example about 90:10, about 91:9, about 95:5, or about 96:4.

The photoacid generator according to some embodiments may be a non-ionic compound, and the non-ionic compound may be represented by any one selected from Chemical Formula 3 to Chemical Formula 6.

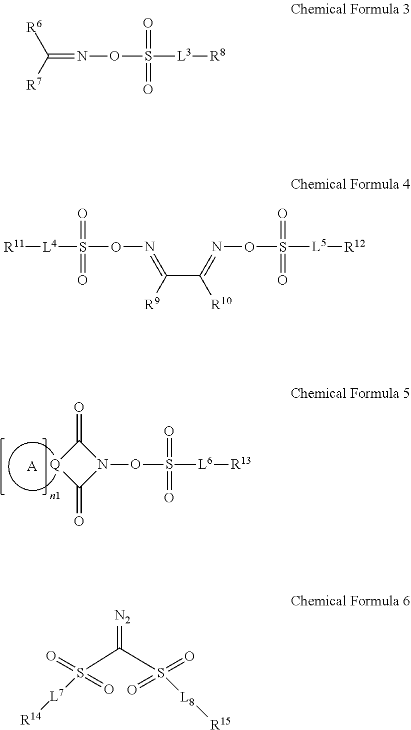

In Chemical Formula 3 to Chemical Formula 6,
R⁶ to R¹⁵ are each independently a halogen, a hydroxy group, an ester group, a substituted or unsubstituted C1 to C20 alkyl group, a substituted or unsubstituted C1 to C20 alkoxy group, a substituted or unsubstituted C2 to C20 alkenyl group, a substituted or unsubstituted C2 to C20 alkynyl group, a substituted or unsubstituted C3 to C20 cycloalkyl group, a substituted or unsubstituted C3 to C20 cycloalkenyl group, a substituted or unsubstituted C6 to C20 aryl group, a substituted or unsubstituted C2 to C20 heterocyclic group, or a combination thereof,
L³ to L⁸ are each independently a single bond (e.g., a single covalent bond), a substituted or unsubstituted C1 to C20 alkylene group, a substituted or unsubstituted C2 to C20 alkenylene group, a substituted or unsubstituted C2 to C20 alkynylene group, a substituted or unsubstituted C3 to C20 cycloalkylene group, a substituted or unsubstituted C3 to C20 cycloalkenylene group, a substituted or unsubstituted C6 to C20 arylene group, a substituted or unsubstituted C2 to C20 heteroarylene group, or a combination thereof,
Q is a substituted or unsubstituted C1 to C10 alkylene group or a substituted or unsubstituted C2 to C10 alkenylene group,
A is a cyclic organic group, and
n1 is an integer of 0 or 1.

The cyclic organic group may be a monocyclic ring compound or a polycyclic ring compound.

Examples of the monocyclic ring compounds may include a cycloalkyl group, a cycloalkenyl group, and the like, and examples thereof may be a substituted or unsubstituted C1 to C20 cycloalkyl group, a substituted or unsubstituted C2 to C20 cycloalkenyl group, and the like.

Further examples of the monocyclic compound may be a substituted or unsubstituted C1 to C10 cycloalkyl group, or a substituted or unsubstituted C2 to C10 cycloalkenyl group, and for example a substituted or unsubstituted cyclopentyl, a substituted or unsubstituted cyclohexyl, a substituted or unsubstituted cycloheptyl, a substituted or unsubstituted cyclooctyl, and the like.

An example of the polycyclic compound may be a bicyclic compound.

The bicyclic compound may include a fused bicyclic compound (e.g., a structure that shares only two atoms between rings, such as decalin), a bridged bicyclic compound (e.g., a structure that shares two atoms between rings and is bridged by additional atoms, such as bicyclo[3,2,1] octane, or a spirocyclic compound (e.g., a structure in which one carbon is shared without a bridge).

As an example, A may be a substituted or unsubstituted cyclopentyl, a substituted or unsubstituted cyclohexyl, a substituted or unsubstituted cycloheptyl, a substituted or unsubstituted cyclooctyl, a substituted or unsubstituted norbornane, substituted or unsubstituted norbornene, substituted or unsubstituted tricyclodecane, a substituted or unsubstituted tetracyclodecane, a substituted or unsubstituted tetracyclododecane, a substituted or unsubstituted adamantane, a substituted or unsubstituted benzene, a substituted or unsubstituted naphthalene, a substituted or unsubstituted phenanthrene, a substituted or unsubstituted anthracene, a substituted or unsubstituted furan, a substituted or unsubstituted thiophene, a substituted or unsubstituted benzothiophene, a substituted or unsubstituted dibenzofuran, a substituted or unsubstituted dibenzothiophene, or a substituted or unsubstituted pyridine.

As an example, A may be a substituted or unsubstituted cyclopentyl, a substituted or unsubstituted cyclohexyl, a substituted or unsubstituted norbornane, substituted or unsubstituted norbornene, a substituted or unsubstituted benzene, a substituted or unsubstituted naphthalene, a substituted or unsubstituted phenanthrene, or a substituted or unsubstituted anthracene.

As an example, R⁶ to R¹⁵ may each independently be a halogen, a hydroxy group, an ester group, a substituted or unsubstituted C1 to C10 alkyl group, a substituted or unsubstituted C1 to C10 alkoxy group, a substituted or unsubstituted C3 to C20 cycloalkyl group, a substituted or unsubstituted C6 to C20 aryl group, a substituted or unsubstituted C2 to C20 heterocyclic group, or a combination thereof.

As an example, R⁶, R⁷, R⁹, and R¹⁰ may each independently be a halogen, a hydroxy group, an ester group, a substituted or unsubstituted methyl group, a substituted or unsubstituted ethyl group, a substituted or unsubstituted propyl group, a substituted or unsubstituted butyl group, a substituted or unsubstituted pentyl group, or a substituted or unsubstituted hexyl group,
R⁸, and R¹¹ to R¹⁵ may each independently be a halogen, a hydroxy group, an ester group, a substituted or unsubstituted methyl group, a substituted or unsubstituted ethyl group, a substituted or unsubstituted propyl group, a substituted or unsubstituted butyl group, a substituted or unsubstituted pentyl group, a substituted or unsubstituted hexyl group, a substituted or unsubstituted substituted or unsubstituted cyclopentyl group, a substituted or unsubstituted cyclohexyl group, a substituted or unsubstituted cycloheptyl group, a substituted or unsubstituted norbornyl group, a substituted or unsubstituted adamantyl group, a substituted or unsubstituted phenyl group, a substituted or unsubstituted biphenyl group, a substituted or unsubstituted naphthyl group, a substituted or unsubstituted phenanthrenyl group, a substituted or unsubstituted anthracenyl group, a substituted or unsubstituted furanyl group, a substituted or unsubstituted thiophenyl group, a substituted or unsubstituted benzothiophenyl group, a substituted or unsubstituted dibenzofuranyl group, a substituted or unsubstituted dibenzothiophenyl group, or a substituted or unsubstituted pyridinyl group.

The non-ionic compound may be at least one selected from the compounds listed in Group IV.

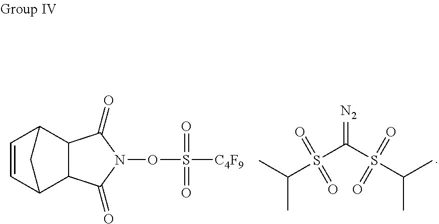

The photoacid generator according to some embodiments may be an ionic compound, and the ionic compound may be represented by Chemical Formula 7 or Chemical Formula 8.

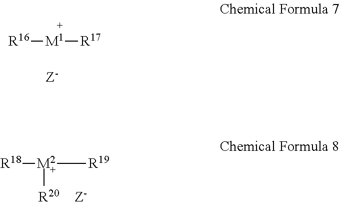

In Chemical Formula 7 and Chemical Formula 8,
M¹ is F, Cl, Br, or I,
M² is O, S, Se, or Te,
R¹⁶ to R²⁰ are each independently a halogen, a hydroxy group, an ester group, a substituted or unsubstituted C1 to C20 alkyl group, a substituted or unsubstituted C1 to C20 alkoxy group, a substituted or unsubstituted C3 to C20 cycloalkyl group, a substituted or unsubstituted C2 to C20 aliphatic unsaturated organic group including one or more double bonds or triple bonds, a substituted or unsubstituted C6 to C30 aryl group, or a combination thereof, and
Z⁻ is an anion derived from a conjugate base of inorganic acid and/or a conjugate base of organic sulfonic acid.

As an example, M1 may be I.

As an example, M2 may be S.

As an example, R¹⁶ to R²⁰ may each independently be a substituted or unsubstituted C6 to C20 aryl group.

For example, the ionic compound represented by Chemical Formula 7 may be represented by Chemical Formula 7-1, and the ionic compound represented by Chemical Formula 8 may be represented by Chemical Formula 8-1.

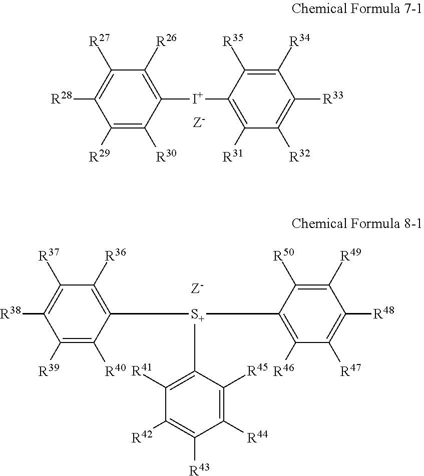

In Chemical Formula 7-1 and Chemical Formula 8-1,
R²⁶ to R⁵⁰ are each independently hydrogen, a halogen, a hydroxy group, an ester group, a substituted or unsubstituted C1 to C20 alkyl group, a substituted or unsubstituted C1 to C20 alkoxy group, a substituted or unsubstituted C6 to C30 aryl group, or a combination thereof, and
Z⁻ is an anion derived from a conjugate base of inorganic acid and/or a conjugate base of organic sulfonic acid.

As an example, Z may be selected from PF₆⁻, BF₄⁻, SbF₆⁻, and organic sulfonic acid anion.

The organic sulfonic acid anion may include both aliphatic sulfonic acid anion and aromatic sulfonic acid anion.

In the aliphatic sulfonic acid anion, the aliphatic may be selected from a substituted or unsubstituted C1 to C30 linear or branched alkyl group and a substituted or unsubstituted C3 to C30 cycloalkyl group.

The substituted or unsubstituted C1 to C30 linear or branched alkyl group and the substituted or unsubstituted C3 to C30 cycloalkyl group may be, for example, a methyl group, an ethyl group, an n-propyl group, an iso-propyl group, an n-butyl group, a sec-butyl group, a tert-butyl group, an n-pentyl group, a tert-pentyl group, a neo-pentyl group, an iso-pentyl group, a sec-pentyl group, a substituted or unsubstituted cyclobutyl group, a substituted or unsubstituted cyclopentyl group, a substituted or unsubstituted cyclohexyl group, a substituted or unsubstituted norbornyl group, a substituted or unsubstituted norbornenyl group, a substituted or unsubstituted adamantyl group, and/or the like.

In the aromatic sulfonic acid anion, the aromatic may be a substituted or unsubstituted C6 to C20 aryl group.

The substituted or unsubstituted C6 to C20 aryl group may be, for example, a substituted or unsubstituted phenyl group, a substituted or unsubstituted biphenyl group, a substituted or unsubstituted naphthyl group, a substituted or unsubstituted tolyl group, a substituted or unsubstituted anthracenyl group, or a substituted or unsubstituted phenanthrenyl group.

As an example, the sulfonic acid anion may be represented by Chemical Formula 9.

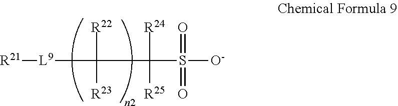

In Chemical Formula 9,
R²¹ is hydrogen, fluoro, a substituted or unsubstituted C1 to C20 alkyl group, a substituted or unsubstituted C2 to C20 aliphatic unsaturated organic group including one or more double bonds or triple bonds, a cyclic organic group, or a combination thereof,
L⁹ is a single bond (e.g., a single covalent bond), O, S, OC(═O), a substituted or unsubstituted C1 to C20 alkylene group, a substituted or unsubstituted C6 to C20 arylene group, or a combination thereof,
R²² to R²⁵ are each independently hydrogen, fluoro, a substituted or unsubstituted C1 to C20 alkyl group, a substituted or unsubstituted C3 to C20 cycloalkyl group, a substituted or unsubstituted C2 to C20 aliphatic unsaturated organic group including one or more double bonds or triple bonds, a substituted or unsubstituted C6 to C30 aryl group, or a combination thereof, and
n2 is one of the integers from 0 to 10.

As an example, at least one selected from R²² to R²⁵ may be fluoro or a C1 to C10 alkyl group substituted with one or more fluoro groups.

For example, at least one selected from R²² to R²⁵ may be fluoro or a C1 to C5 alkyl group substituted with one or more fluoro groups.

For example, the C1 to C5 alkyl group substituted with one or more fluoro groups may include CF₃, C₂F₅, C₃F₇, C₄F₉, CH₂CF₃, CH₂CH₂CF₃, CH₂C₂F₅, CH₂CH₂C₂F₅, CH₂C₃F₇, CH₂CH₂C₃F₇, CH₂C₄F₉, and/or CH₂CH₂C₄F₉.

The ionic compound may be at least one selected from the compounds listed in Group V.

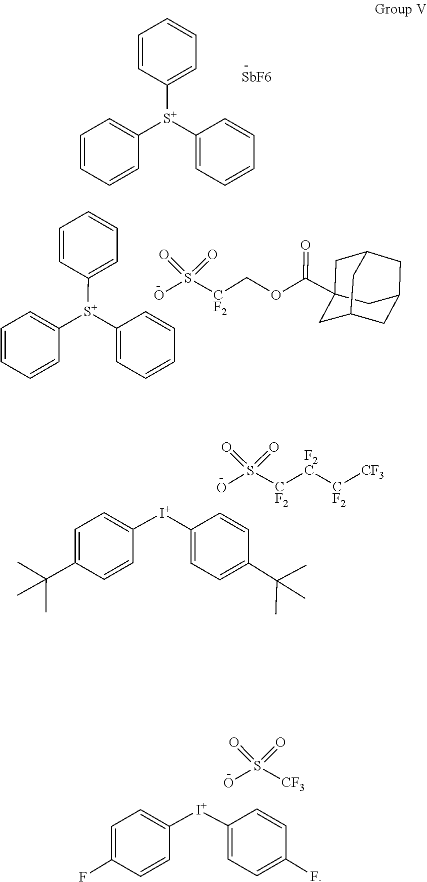

The photoacid generator may be included in an amount of about 0.1 parts by weight to about 40 parts by weight, for example about 0.1 parts by weight to about 30 parts by weight, for example about 0.5 parts by weight to about 30 parts by weight based on 100 parts by weight of the copolymer. Within the above ranges, solubility can be optimized or improved and pattern LWR improvement effect can be secured.

In embodiments, the resist topcoat composition may further include at least one other polymer selected from an epoxy-based resin, a novolac resin, a glycoluril-based resin, and a melamine-based resin, but is not limited thereto.

The resist topcoat composition may further include an additive including a surfactant, a thermal acid generator, a plasticizer, or a combination thereof.

The surfactant may be, for example, an alkylbenzene sulfonic acid salt, an alkylpyridinium salt, polyethylene glycol, a quaternary ammonium salt, and/or the like, but is not limited thereto.

The thermal acid generator may be, for example, an acid compound such as p-toluene sulfonic acid, trifluoromethanesulfonic acid, pyridinium p-toluene sulfonic acid, salicylic acid, sulfosalicylic acid, citric acid, benzoic acid, hydroxybenzoic acid, naphthalene carboxylic acid and/or benzoin tosylate, 2-nitrobenzyl tosylate, and/or other organic sulfonic acid alkyl esters, but is not limited thereto.

The amount of these additives used can be easily adjusted according to suitable or desired physical properties or these additives may be omitted.

The solvent may be an ether-based solvent, and may be, for example, represented by Chemical Formula 10.

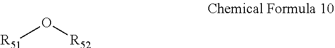

In Chemical Formula 10,
R⁵¹ and R⁵² are each independently a substituted or unsubstituted C3 to C20 alkyl group.

For example, the ether-based solvent may be selected from diisopropyl ether, dipropyl ether, diisoamyl ether, diamyl ether, dibutyl ether, diisobutyl ether, di-sec-butyl ether, dihexyl ether, bis(2-ethylhexyl) ether, didecyl ether, diundecyl ether, didodecyl ether, ditetradecyl ether, hexadecyl ether, butyl methyl ether, butyl ethyl ether, butyl propyl ether, tert-butyl methyl ether, tert-butyl ethyl ether, tert-butylpropyl ether, di-tert-butyl ether, cyclopentylmethyl ether, cyclohexylmethyl ether, cyclopentylethyl ether, cyclohexylethyl ether, cyclopentylpropyl ether, cyclopentyl-2-propyl ether, cyclohexylpropyl ether, cyclohexyl-2-propyl ether, cyclopentylbutyl ether, cyclopentyl-tert-butyl ether, cyclohexylbutyl ether, cyclohexyl-tert-butyl ether, 2-octanone, 4-heptanone, and a combination thereof.

The ether-based solvent may have suitable or sufficient solubility and/or dispersibility for the aforementioned composition.

According to some example embodiments, a method of forming patterns using the aforementioned photoresist topcoat composition may be provided. For example, the manufactured pattern may be a photoresist pattern.

A method of forming patterns according to some example embodiments includes coating and heating a photoresist composition on a substrate to form a photoresist layer, coating and heating the aforementioned photoresist topcoat composition on the photoresist layer to form a topcoat, and exposing and developing the topcoat and the photoresist layer to form a resist pattern.

Hereinafter, a method of forming patterns using the aforementioned photoresist topcoat composition will be described with reference to the accompanying drawing. The accompanying drawing is a schematic view illustrating a method of forming patterns using a photoresist topcoat composition according to embodiments of the present disclosure.

Referring to the accompanying drawing, first, an object 100 to be etched is prepared. An example of the object to be etched may be a thin film on a semiconductor substrate. Hereinafter, only embodiments where the object to be etched is a thin film will be described, but the present disclosure is not limited thereto. The surface of the thin film is cleaned to remove contaminants remaining on the thin film. The thin film may be, for example, a silicon nitride film, a polysilicon film, and/or a silicon oxide film.

A photoresist composition is coated on the thin film and heated to form a photoresist layer 101 (Act 1). Subsequently, the photoresist topcoat composition is coated on the photoresist layer and heated to form a photoresist topcoat 30 (Act 2).

The heating may be performed at a temperature of about 80° C. to about 500° C.

Then, the photoresist topcoat and the photoresist layer are exposed to high-energy radiation.

For example, the high-energy radiation that can be used in the exposure process may include light having a high-energy wavelength, such as EUV (Extreme Ultraviolet; wavelength: 13.5 nm) and/or E-Beam (electron beam).

A post-exposure heat treatment (PEB) is then performed. The post-exposure heat treatment may be performed at a temperature of about 80° C. to about 200° C. By performing the post-exposure heat treatment, the exposed region of the photoresist layer, for example, the region not covered by the patterned mask is changed to a property that is soluble in a developer, so that the exposed region has a different solubility from that of the unexposed region of the photoresist layer.

A photoresist pattern 102b may be formed by dissolving and removing the photoresist layer corresponding to the exposed region and the photoresist topcoat using a developer (Act 3).

In embodiments, the developer may be an alkaline developer or a developer containing an organic solvent (hereinafter referred to as an organic-based developer).

As the alkaline developer, a quaternary ammonium salt such as tetramethylammonium hydroxide is may be used, but aqueous alkaline solutions such as inorganic alkalis, primary to tertiary amines, alcohol amines, and/or cyclic amines may also be used.

In embodiments, the alkaline developer may contain alcohol and/or surfactant in a suitable or appropriate amount. An alkaline concentration of the alkaline developer may be, for example, about 0.1 to about 20 mass %, and a pH of the alkaline developer may be, for example, about 10 to about 15.

The organic-based developer may be a developer containing at least one organic solvent selected from the group consisting of ketone solvents, ester solvents, alcohol solvents, amide solvents, ether solvents, and hydrocarbon solvents.

Examples of the ketone solvent may include 1-octanone, 2-octanone, 1-nonanone, 2-nonanone, acetone, 2-heptanone (methyl amyl ketone), 4-heptanone, 1-hexanone, 2-hexanone, diisobutyl ketone, cyclohexanone, methylcyclohexanone, phenylacetone, methyl ethyl ketone, methyl isobutyl ketone, acetylacetone, acetonyl acetone, ionone, diacetonyl alcohol, acetyl carbinol, acetophenone, methyl naphthyl ketone, isophorone, propylene carbonate, and the like.

Examples of the ester solvent may include methyl acetate, butyl acetate, ethyl acetate, isopropyl acetate, pentyl acetate, isopentyl acetate, amyl acetate, propylene glycol monomethyl ether acetate, ethylene glycol monoethyl ether acetate, ethylene glycol monobutyl ether acetate, ethylene glycol monoethyl ether acetate, ethyl-3-ethoxypropionate, 3-methoxybutyl acetate, 3-methyl-3-methoxybutyl acetate, methyl formate, ethyl formate, butyl formate, propyl formate, ethyl lactate, butyl lactate, propyl lactate, butyl butanoate, methyl 2-hydroxyisobutyrate, isoamyl acetate, isobutyl isobutyrate, butyl propionate, and the like.

Any suitable solvents generally used in the art may be used as alcohol solvents, amide solvents, ether solvents, and hydrocarbon solvents.

A plurality of said solvents may be mixed together, or may be mixed together with solvents or water other than the above-described solvents. A moisture content as a whole of the developer may be suitably or desirably less than about 50 wt %, less than about 20 wt %, less than about 10 wt %, or, for example, the developer may be substantially free of moisture.

A content of the organic solvent may be suitably or desirably about 50 to about 100 wt %, about 80 to about 100 wt %, about 90 to about 100 wt %, or, for example, about 95 to about 100 wt % based on a total amount of the organic developer.

The organic developer may include a suitable or appropriate amount of any suitable surfactant generally used in the art as required or desired.

A content of the surfactant may be about 0.001 to about 5 wt %, about 0.005 to about 2 wt %, or, for example, about 0.01 to about 0.5 wt % based on a total amount of the developer.

The organic developer may include any suitable inhibitor generally used in the art.

Subsequently, the exposed thin film is etched by applying the photoresist pattern as an etching mask. As a result, the thin film is formed into a thin film pattern.

The thin film may be etched, for example, by dry etching using an etching gas, and the etching gas may be, for example, CHF₃, CF₄, Cl₂, BCl₃, and/or a mixture thereof.

In the exposure process performed above, the thin film pattern formed using the photoresist pattern that is formed by the exposure process performed using the EUV light source may have a width corresponding to the photoresist pattern. For example, the photoresist pattern may have a width of about 5 nm to about 100 nm. For example, the thin film pattern formed by the exposure process performed using an EUV light source may have a width of about 5 nm to about 90 nm, about 5 nm to about 80 nm, about 5 nm to about 70 nm, about 5 nm to about 60 nm, about 5 nm to about 50 nm, about 5 nm to about 40 nm, about 5 nm to about 30 nm, about 5 nm to about 20 nm, or may be formed to have a width of less than or equal to about 20 nm, like the photoresist pattern.

Hereinafter, embodiments of the present disclosure will be described in more detail through examples relating to the synthesis of the aforementioned polymer and the preparation of a photoresist topcoat composition including the same. However, the present disclosure is not technically limited by the following examples.

### SYNTHESIS EXAMPLES

### Synthesis Example 1: Synthesis of Compound 1a

20 g (59.86 mmol) of hexafluoro-2,3-bis(trifluoromethyl)-2,3-butanediol (perfluoropinacol), 7.79 g (59.86 mmol) of 2-(hydroxyethyl) methacrylate, and 18.84 g (71.84 mmol) of triphenylphosphine (PH₃P) were mixed together in 110 m1 of diethylether under a nitrogen atmosphere and then, stirred. After the stirring for 30 minutes, the resultant mixture was cooled down to 0° C., and another mixture of 14.52 g (71.84 mmol) of diisopropyl azodicarboxylate (DIAD) and 35 ml of diethylether was slowly added thereto over 2 hours. Subsequently, the obtained mixture was stirred at room temperature (23° C.) for 24 hours and then, concentrated. The concentrated mixture was dissolved in dichloromethane and then, treated through column chromatography by using silica gel to separate a synthesized material. The separated material was distilled under a reduced pressure, obtaining 2-[3,3,3-trifluoro-2-hydroxy-1,1,2-tris(trifluoromethyl)propoxy]ethyl 2-methyl-2-propenoate represented by Chemical Formula 1a.

¹H-NMR (Acetone-d6): δ1.90 (3H, t), 4.36 (4H, m), 5.63 (1H, t), 6.09 (1H, t), 8.34 (1H, s)

¹⁹F-NMR (Acetone-d6): δ−70.12 (6F, m), −65.38 (6F, m)

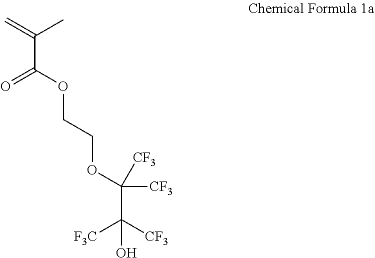 [SMILES: C=C(C)C(=O)OCCOC(C(F)(F)F)(C(F)(F)F)C(O)(C(F)(F)F)C(F)(F)F]

### Synthesis Example 2: Preparation of Copolymer R1

In a 250 mL 2-neck round bottom flask, a compound represented by Chemical Formula 1a (16.1 g, 36 mmol), a compound represented by Chemical Formula 1b (DIVPA, Songwon) (1.7 g, 4 mmol), and 110 g of diisoamyl ether (DIAE) were added under a nitrogen atmosphere and then, heated to 100° C. When the internal temperature reached 85° C., 14.7 g of a 25 wt % V-601/DIAE solution (V-601, 3.7 g, 16 mmol) was slowly added thereto, and after 6 hours, the resultant reaction solution was cooled to room temperature and then, concentrated to have a solid content of 50%. 270 g of heptane was added to the concentrated solution, and a polymer produced therefrom was filtered. The filtered polymer was completely dissolved in 34 g of DIAE, and 270 g of heptane was added thereto for precipitation, which were twice repeated to obtain precipitates, and the precipitates were completely dried, preparing final Copolymer R1 (Mw=4,000).

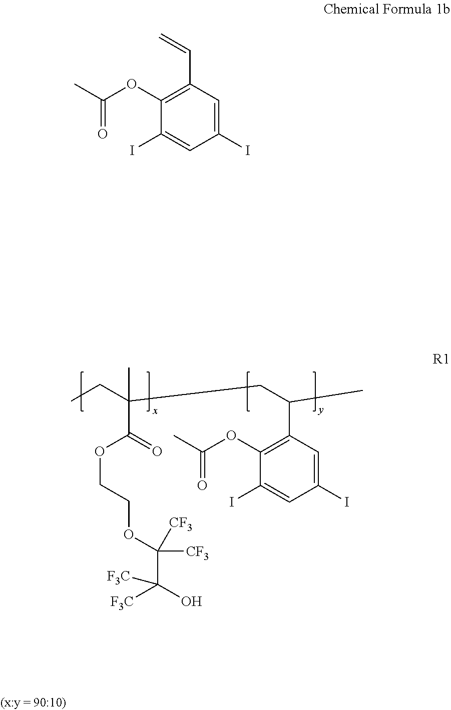

### Synthesis Example 3: Preparation of Copolymer R2

Copolymer R² (Mw=9,000) was prepared in substantially the same manner as in Synthesis Example 2 except that a compound represented by Chemical Formula 2b (1.5 g, 16 mmol) (2,4-diiodo-6-vinylphenol, Accela Chembio Inc.) was used instead of the compound represented by Chemical Formula 1b.

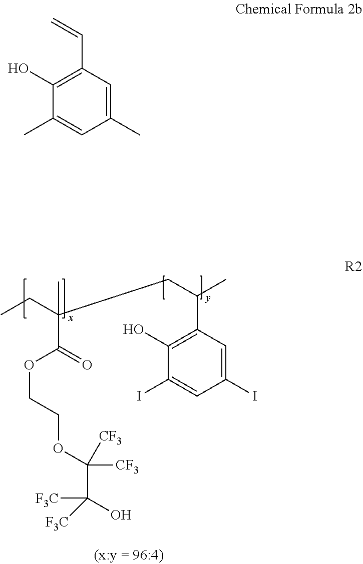

### Synthesis Example 4: Preparation of Copolymer R3

Copolymer R3 (Mw=5,000) was prepared in substantially the same manner as in Synthesis Example 2 except that a compound represented by Chemical Formula 2a (10.6 g, 36 mmol) was used instead of the compound represented by Chemical Formula 1b.

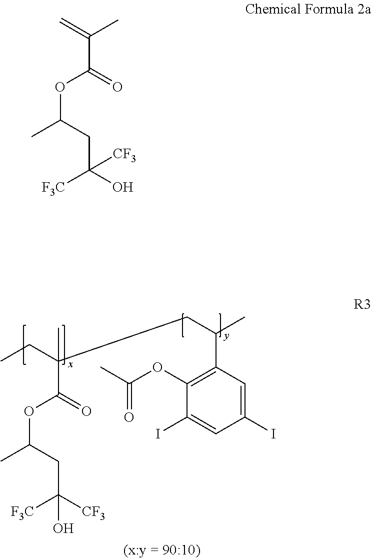

### Synthesis Example 5: Preparation of Copolymer R4

Copolymer R4 (Mw=6,000) was prepared in substantially the same manner as in Synthesis Example 2 except that a compound represented by Chemical Formula 2a (16.1 g, 36 mmol) instead of the compound represented by Chemical Formula 1a and a compound (1.5 g, 4 mmol) represented by Chemical Formula 2b (16.1 g, 36 mmol) instead of the compound represented by Chemical Formula 1b were used.

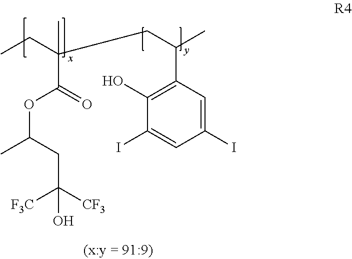

### Synthesis Example 6: Preparation of Copolymer R5

Copolymer R5 (Mw=5,000) was prepared in substantially the same manner as in Synthesis Example 2 except that a compound represented by Chemical Formula 3a (10.1 g, 36 mmol) (MA-TTBD, HALOCARBON) was used instead of the compound represented by Chemical Formula 1a.

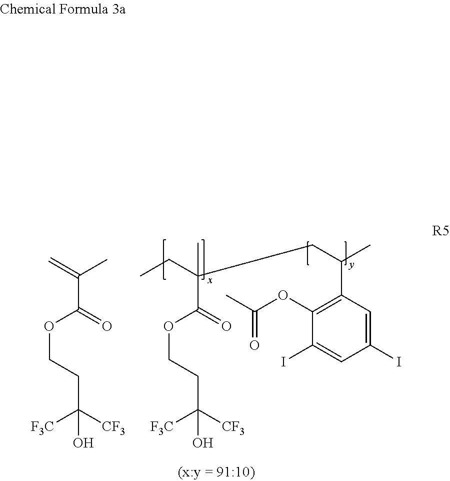

### Synthesis Example 7: Preparation of Copolymer R6

Copolymer R6 (Mw=5,000) was prepared in substantially the same manner as in Synthesis Example 2 except that a compound represented by Chemical Formula 3a (10.1 g, 36 mmol) instead of the compound represented by Chemical Formula 1a and a compound (1.5 g, 4 mmol) represented by Chemical Formula 2b (1.5 g, 4 mmol) instead of the compound represented by Chemical Formula 1b were used.

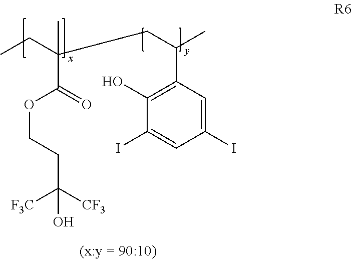

### Synthesis Example 8: Preparation of Copolymer R7

Copolymer R7 (Mw=5,000) was prepared in substantially the same manner as in Synthesis Example 2, except that the compound represented by Formula 1b was not used.

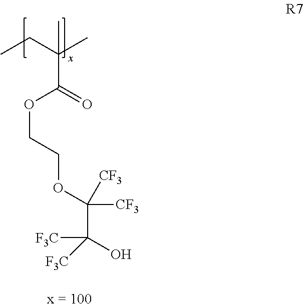

### Preparation of Resist Topcoat Compositions

### Example 1

0.98 g (0.5 wt %) of Copolymer R¹ according to Synthesis Example 2 and 1.47 mg (0.15 wt %) of a photoacid generator represented by P1 were dissolved in 199 g of a mixed solvent of DIAE/PGME (w/w=97/3) and then, stirred at room temperature (23° C.) for 24 hours and filtered through a TEFLON (tetrafluoroethylene) filter having a pore size of 0.45 μm, preparing a resist topcoat composition.

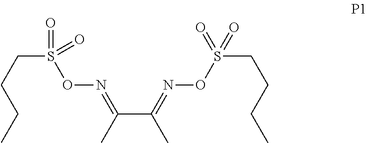 [SMILES: CCCCS(=O)(=O)O/N=C(C)/C(C)=N/OS(=O)(=O)CCCC]

### Examples 2 to 34

Each resist topcoat composition was prepared in substantially the same manner as in Example 1 except that types of the copolymer and types of the photoacid generator were changed as shown in Table 1.

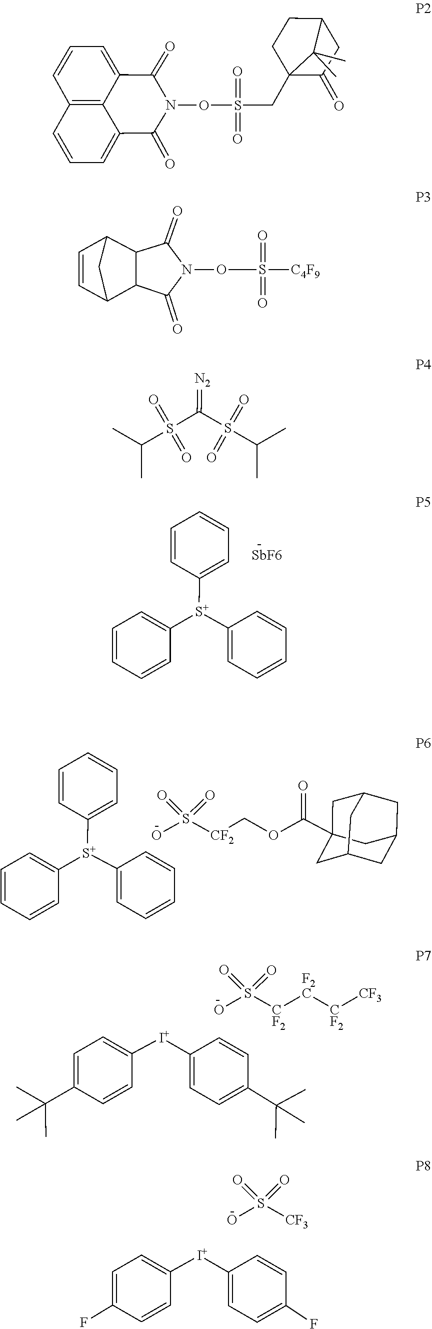

### Comparative Example 1

A resist topcoat composition was prepared in substantially the same manner as in Example 1 except that the photoacid generator was not used.

### Comparative Example 2

A resist topcoat composition was prepared in substantially the same manner as in Example 1 except that Copolymer R7 of Synthesis Example 8 was used instead of Copolymer R1.

### Evaluation 1: Solubility Evaluation

Each of the compositions according to Examples 1 to 34 and Comparative Examples 1 and 2 was stirred for 24 hours and examined with respect to presence or absence of precipitates with naked eyes (without magnification), and the results are shown in Table 1.
(absence of precipitation—solubility ∘, presence of precipitation—solubility X)

### Evaluation 2: Developability Evaluation

Each of the photoresist topcoat compositions prepared in the Examples and the Comparative Examples was spin-coated on a silicon substrate and heat-treated at 110° C. on a hot plate for 1 minute, to form an about 5 nm-thick photoresist topcoat. The substrate having a topcoat formed thereon was rinsed with 2.38% tetramethylammonium hydroxide aqueous solution and heat-treated again at 110° C. on the hot plate for 1 minute and then, measured with respect to a thickness change of the topcoat layer, and the results are shown in Table 1.

$${*}^{} Residual film after development ( \% ) = [ Topcoat thickness before development ( nm ) - Topcoat thickness after development ( nm ) ] \times 100 / Topcoat thickness before development ( nm )$$

$$( Residual film after development \leq 20 \% - Developability O , Topcoat thickness after development > 20 \% - Developability X )$$

### Evaluation 3: Sensitivity Evaluation

After forming a resist underlayer (thickness: 50 Å) and a photoresist thin film for EUV (a thickness: 700 Å) on a 12-inch silicon substrate, each of the photoresist topcoat compositions according to the Examples and the Comparative Examples was spin-coated and then, heat-treated at 110° C. for 1 minute on a hot plate to form about 5 nm-thick topcoats for photoresist.

A Line & Space pattern was formed in Focus-Energy Matrix (FEM) format on the wafer on which the topcoat for photoresist was formed using the NXE3400B EUV equipment. The sensitivity capable of forming a Critical Dimension (CD) of 26.0 nm was confirmed using the interpolation method, and the results are shown in Table 1.

TABLE 1

| | | Photoacid | | | Sensitivity |
|---|---|---|---|---|---|
| | Copolymer | generator | Solubility | Developability | (mJ/cm²) |
| Example 1 | R1 | P1 | ∘ | ∘ | 43.4 |
| Example 2 | R2 | P1 | ∘ | ∘ | 43.2 |
| Example 3 | R3 | P1 | ∘ | ∘ | 44.4 |
| Example 4 | R4 | P1 | ∘ | ∘ | 44.2 |
| Example 5 | R5 | P1 | ∘ | ∘ | 44.3 |
| Example 6 | R6 | P1 | ∘ | ∘ | 44.1 |
| Example 7 | R1 | P2 | ∘ | ∘ | 41.1 |
| Example 8 | R2 | P2 | ∘ | ∘ | 41.0 |
| Example 9 | R3 | P2 | ∘ | ∘ | 42.1 |
| Example 10 | R4 | P2 | ∘ | ∘ | 41.9 |
| Example 11 | R1 | P3 | ∘ | ∘ | 40.2 |
| Example 12 | R2 | P3 | ∘ | ∘ | 40.1 |
| Example 13 | R3 | P3 | ∘ | ∘ | 41.2 |
| Example 14 | R4 | P3 | ∘ | ∘ | 40.9 |
| Example 15 | R1 | P4 | ∘ | ∘ | 42.5 |
| Example 16 | R2 | P4 | ∘ | ∘ | 42.3 |
| Example 17 | R3 | P4 | ∘ | ∘ | 43.5 |
| Example 18 | R4 | P4 | ∘ | ∘ | 43.2 |
| Example 19 | R1 | P5 | ∘ | ∘ | 37.1 |
| Example 20 | R2 | P5 | ∘ | ∘ | 36.9 |
| Example 21 | R3 | P5 | ∘ | ∘ | 38.0 |
| Example 22 | R4 | P5 | ∘ | ∘ | 37.7 |
| Example 23 | R1 | P6 | ∘ | ∘ | 36.2 |
| Example 24 | R2 | P6 | ∘ | ∘ | 36.0 |
| Example 25 | R3 | P6 | ∘ | ∘ | 37.0 |
| Example 26 | R4 | P6 | ∘ | ∘ | 36.8 |
| Example 27 | R1 | P7 | ∘ | ∘ | 38.4 |
| Example 28 | R2 | P7 | ∘ | ∘ | 38.3 |
| Example 29 | R3 | P7 | ∘ | ∘ | 39.4 |
| Example 30 | R4 | P7 | ∘ | ∘ | 39.1 |
| Example 31 | R1 | P8 | ∘ | ∘ | 39.3 |
| Example 32 | R2 | P8 | ∘ | ∘ | 39.2 |
| Example 33 | R3 | P8 | ∘ | ∘ | 40.3 |
| Example 34 | R4 | P8 | ∘ | ∘ | 40.0 |
| Comparative Example 1 | R1 | — | ∘ | ∘ | 45.2 |
| Comparative Example 2 | R7 | P1 | ∘ | ∘ | 50.3 |

Referring to Table 1, if the resist topcoat composition according to an example embodiment was applied, it was confirmed that solubility and developability were not only excellent, but also, as acid generation was promoted in an exposed region, sensitivity was excellent.

On the contrary, the resist topcoat compositions according to the Comparative Examples exhibited no improved sensitivity or exhibited deteriorated sensitivity.

Hereinbefore, certain embodiments have been described and illustrated, however, it should be apparent to a person having ordinary skill in the art that the present disclosure is not limited to the embodiments as described, and may be variously suitably modified and transformed without departing from the spirit and scope of the present disclosure. Accordingly, the modified or transformed embodiments as such may not be understood separately from the technical ideas and aspects of the present disclosure, and the modified embodiments are within the scope of the appended claims, and equivalents thereof.

### DESCRIPTION OF SYMBOLS

1: forming a photoresist layer
2: forming a photoresist topcoat
3: exposing and developing the photoresist layer and the photoresist topcoat to form a resist pattern
30: photoresist topcoat
100: substrate
101: photoresist layer
102b: photoresist pattern

What is claimed is:

1. A resist topcoat composition, comprising:
a copolymer comprising a first structural unit represented by Chemical Formula M-1 and a second structural unit represented by Chemical Formula M-2;
a photoacid generator; and
a solvent,
wherein the photoacid generator is a non-ionic compound or an ionic compound,
the non-ionic compound comprises an organic sulfonate group, and
the ionic compound comprises at least one selected from a conjugate base of an inorganic acid and a conjugate base of an organic sulfonic acid as an anion: 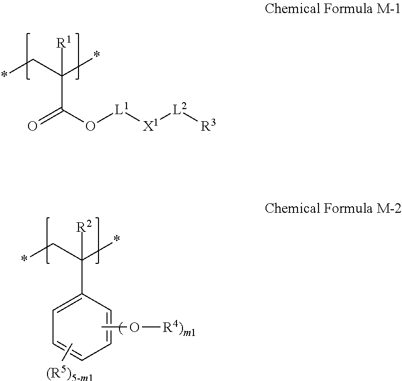
wherein, in Chemical Formula M-1 and Chemical Formula M-2,
R¹ and R² are each independently hydrogen or a substituted or unsubstituted C1 to C10 alkyl group,
L¹ and L² are each independently a single bond, a substituted or unsubstituted C1 to C10 alkylene group, or a combination thereof,
X¹ is a single bond, —O—, —S—, —S(O)—, —S(O)₂—, —C(O)—, —(CO)O—, —O(CO), —O(CO)O—, —NR^{a}— (wherein, R^{a} is hydrogen, deuterium, or a substituted or unsubstituted C1 to C10 alkyl group), or a combination thereof,
R³ is hydrogen, fluorine, a hydroxy group, a substituted or unsubstituted C1 to C20 alkyl group, or a combination thereof,
R⁴ is hydrogen, or C(═O)R^{b},
R^{b} is a substituted or unsubstituted C1 to C10 alkyl group,
at least one selected from R³, L¹, and L² comprises fluorine and a hydroxy group,
R⁵ is hydrogen, a halogen, a hydroxy group, a substituted or unsubstituted C1 to C10 alkyl group, or a combination thereof,
m1 is one an integer from 1 to 4, and
* is a linking point.

2. The resist topcoat composition as claimed in claim 1, wherein:
the first structural unit is represented by Chemical Formula 1: 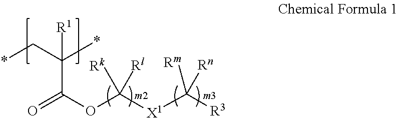
wherein, in Chemical Formula 1,
R¹ is hydrogen or a substituted or unsubstituted C1 to C10 alkyl group,
R^{k}, R^{l}, R^{m}, Rⁿ, and R³ are each independently hydrogen, fluorine, a hydroxy group, a substituted or unsubstituted C1 to C20 alkyl group, or a combination thereof,
m2 and m3 are each independently an integer from 1 to 10,
X¹ is a single bond, —O—, —S—, —S(O)—, —S(O)₂—, —C(O)—, —(CO)O—, —O(CO), —O(CO)O—, —NR^{a}— (wherein, R^{a} is hydrogen, deuterium, or a substituted or unsubstituted C1 to C10 alkyl group), or a combination thereof, and
at least one selected from R^{k}, R^{l}, R^{m}, Rⁿ, and R³ includes fluorine and a hydroxy group.

3. The resist topcoat composition as claimed in claim 1, wherein:
the first structural unit is at least one selected from Group I: 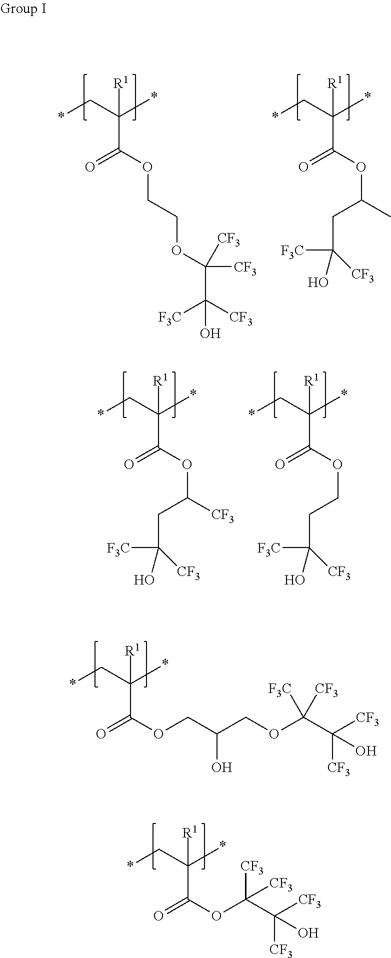
wherein, in Group I,
R¹ is each independently hydrogen or a methyl group, and * is a linking point.

4. The resist topcoat composition as claimed in claim 1, wherein:
the second structural unit is represented by any one selected from Chemical Formula 2-1 to Chemical Formula 2-4: 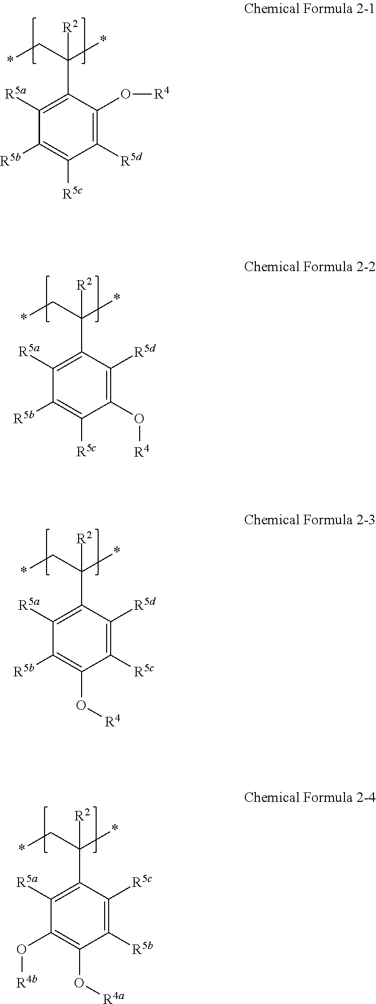
wherein, in Chemical Formula 2-1 to Chemical Formula 2-4,
R² is hydrogen or a methyl group,
R⁴, R^{4a}, and R^{4b} are each independently hydrogen, or C(═O)R^{b},
R^{b} is a substituted or unsubstituted C1 to C5 alkyl group,
R^{5a}, R^{5b}, R^{5c}, and R^{5d} are each independently hydrogen, a halogen, a hydroxy group, a substituted or unsubstituted C1 to C10 alkyl group, or a combination thereof, and
* is a linking point.

5. The resist topcoat composition as claimed in claim 4, wherein:
at least one selected from R^{5a}, R^{5b}, R^{5c}, and R^{5d} is an iodine group.

6. The resist topcoat composition as claimed in claim 1, wherein:
the second structural unit is at least one selected from Group II: 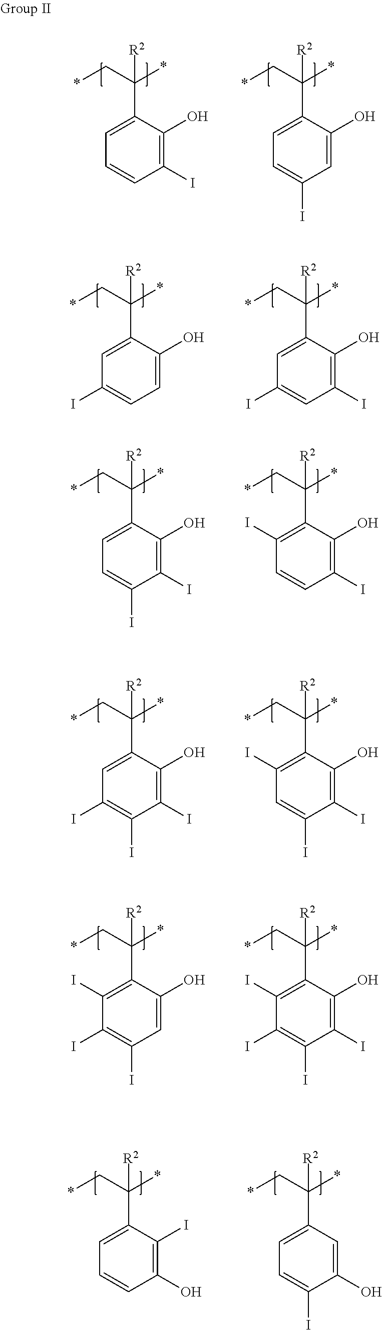 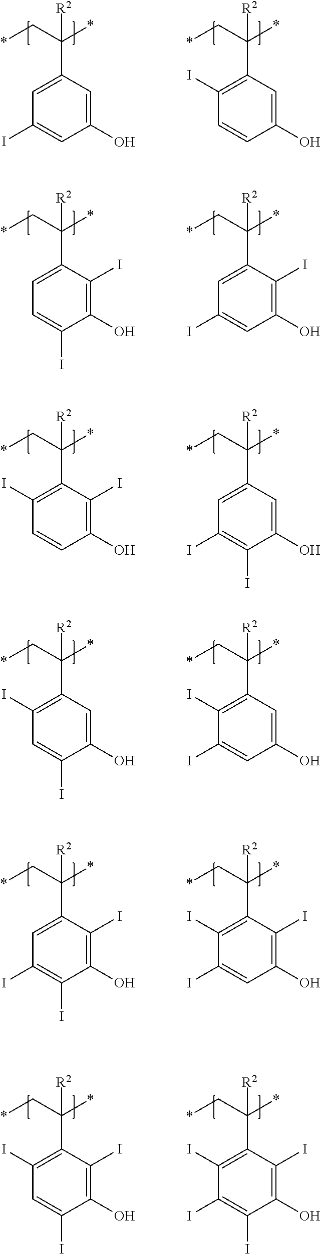 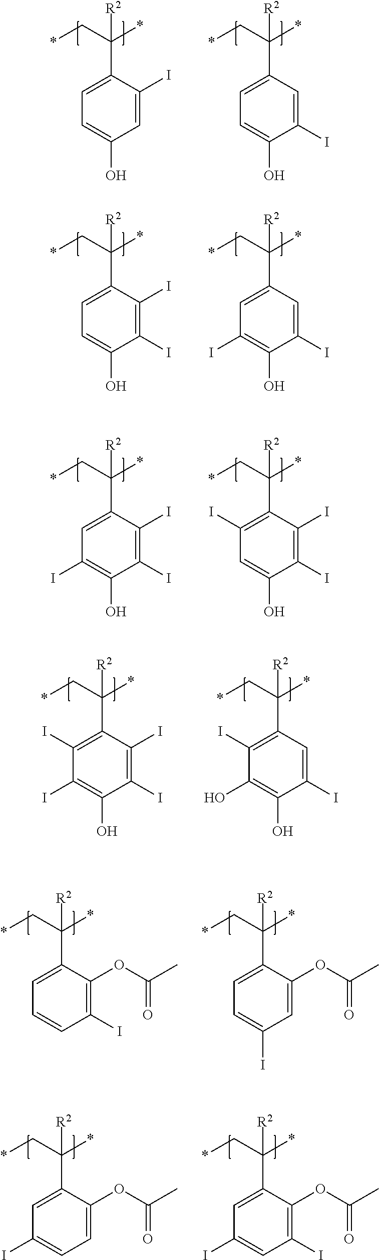 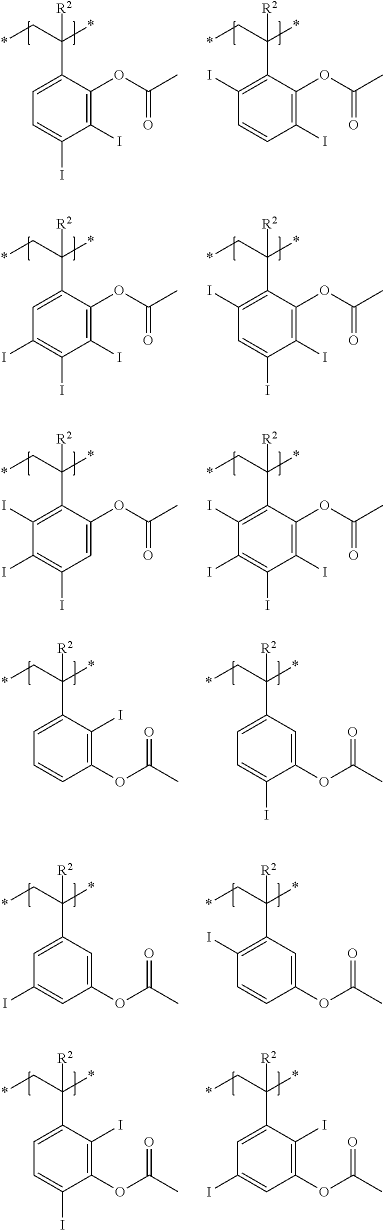 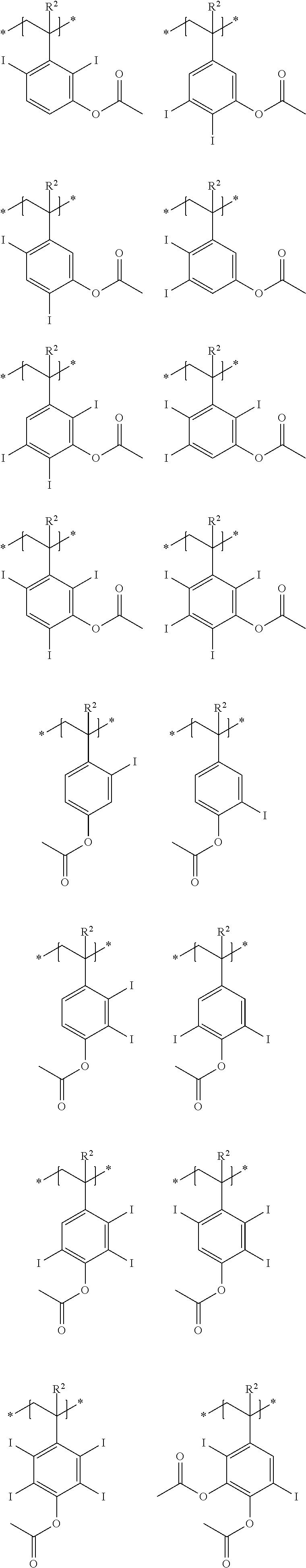
wherein, in Group II,
R² is each independently hydrogen or a methyl group, and * is a linking point.

7. The resist topcoat composition as claimed in claim 1, wherein:
the copolymer comprises the first structural unit in an amount of about 50 to about 99 mol % and the second structural unit in an amount of about 1 to about 50 mol %.

8. The resist topcoat composition as claimed in claim 1, wherein:
the copolymer has a weight average molecular weight of about 1,000 g/mol to about 50,000 g/mol.

9. The resist topcoat composition as claimed in claim 1, wherein:
the non-ionic compound is represented by any one selected from Chemical Formula 3 to Chemical Formula 6: 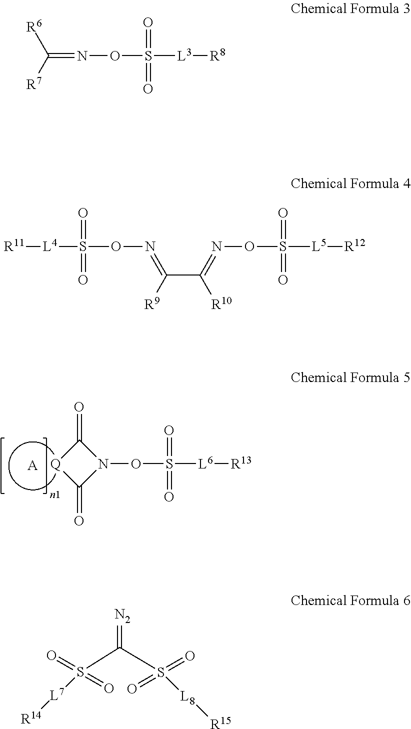
wherein, in Chemical Formula 3 to Chemical Formula 6,
R⁶ to R¹⁵ are each independently a halogen, a hydroxy group, an ester group, a substituted or unsubstituted C1 to C20 alkyl group, a substituted or unsubstituted C1 to C20 alkoxy group, a substituted or unsubstituted C2 to C20 alkenyl group, a substituted or unsubstituted C2 to C20 alkynyl group, a substituted or unsubstituted C3 to C20 cycloalkyl group, a substituted or unsubstituted C3 to C20 cycloalkenyl group, a substituted or unsubstituted C6 to C20 aryl group, a substituted or unsubstituted C2 to C20 heterocyclic group, or a combination thereof,
L³ to L⁸ are each independently a single bond, a substituted or unsubstituted C1 to C20 alkylene group, a substituted or unsubstituted C2 to C20 alkenylene group, a substituted or unsubstituted C2 to C20 alkynylene group, a substituted or unsubstituted C3 to C20 cycloalkylene group, a substituted or unsubstituted C3 to C20 cycloalkenylene group, a substituted or unsubstituted C6 to C20 arylene group, a substituted or unsubstituted C2 to C20 heteroarylene group, or a combination thereof,
Q is a substituted or unsubstituted C1 to C10 alkylene group or a substituted or unsubstituted C2 to C10 alkenylene group,
A is a cyclic organic group, and
n1 is an integer of 0 or 1.

10. The resist topcoat composition as claimed in claim 9, wherein:
A is a substituted or unsubstituted cyclopentyl, a substituted or unsubstituted cyclohexyl, a substituted or unsubstituted cycloheptyl, a substituted or unsubstituted cyclooctyl, a substituted or unsubstituted norbornane, substituted or unsubstituted norbornene, substituted or unsubstituted tricyclodecane, a substituted or unsubstituted tetracyclodecane, a substituted or unsubstituted tetracyclododecane, a substituted or unsubstituted adamantane, a substituted or unsubstituted benzene, a substituted or unsubstituted naphthalene, a substituted or unsubstituted phenanthrene, a substituted or unsubstituted anthracene, a substituted or unsubstituted furan, a substituted or unsubstituted thiophene, a substituted or unsubstituted benzothiophene, a substituted or unsubstituted dibenzofuran, a substituted or unsubstituted dibenzothiophene, or a substituted or unsubstituted pyridine.

11. The resist topcoat composition as claimed in claim 9, wherein:
R⁶, R⁷, R⁹, and R¹⁰ are each independently a halogen, a hydroxy group, an ester group, a substituted or unsubstituted methyl group, a substituted or unsubstituted ethyl group, a substituted or unsubstituted propyl group, a substituted or unsubstituted butyl group, a substituted or unsubstituted pentyl group, or a substituted or unsubstituted hexyl group, and
R⁸, R¹¹, to R¹⁵ are each independently a halogen, a hydroxy group, an ester group, a substituted or unsubstituted methyl group, a substituted or unsubstituted ethyl group, a substituted or unsubstituted propyl group, a substituted or unsubstituted butyl group, a substituted or unsubstituted pentyl group, a substituted or unsubstituted hexyl group, a substituted or unsubstituted substituted or unsubstituted cyclopentyl group, a substituted or unsubstituted cyclohexyl group, a substituted or unsubstituted cycloheptyl group, a substituted or unsubstituted norbornyl group, a substituted or unsubstituted adamantyl group, a substituted or unsubstituted phenyl group, a substituted or unsubstituted biphenyl group, a substituted or unsubstituted naphthyl group, a substituted or unsubstituted phenanthrenyl group, a substituted or unsubstituted anthracenyl group, a substituted or unsubstituted furanyl group, a substituted or unsubstituted thiophenyl group, a substituted or unsubstituted benzothiophenyl group, a substituted or unsubstituted dibenzofuranyl group, a substituted or unsubstituted dibenzothiophenyl group, or a substituted or unsubstituted pyridinyl group.

12. The resist topcoat composition as claimed in claim 1, wherein:
the non-ionic compound is at least one selected from compounds listed in Group IV:

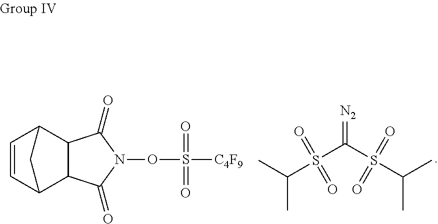

13. The resist topcoat composition as claimed in claim 1, wherein:
the ionic compound is represented by Chemical Formula 7 or Chemical Formula 8: 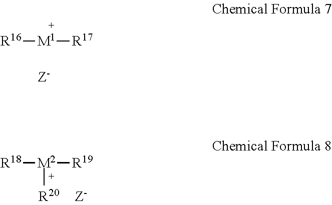
wherein, in Chemical Formula 7 and Chemical Formula 8,
M¹ is F, Cl, Br, or I,
M² is O, S, Se, or Te,
R¹⁶ to R²⁰ are each independently a halogen, a hydroxy group, an ester group, a substituted or unsubstituted C1 to C20 alkyl group, a substituted or unsubstituted C1 to C20 alkoxy group, a substituted or unsubstituted C3 to C20 cycloalkyl group, a substituted or unsubstituted C2 to C20 aliphatic unsaturated organic group including one or more double bonds or triple bonds, a substituted or unsubstituted C6 to C30 aryl group, or a combination thereof, and
Z⁻ is an anion derived from a conjugate base of inorganic acid or a conjugate base of organic sulfonic acid.

14. The resist topcoat composition as claimed in claim 13, wherein:
the ionic compound is represented by Chemical Formula 7-1 or Chemical Formula 8-1: 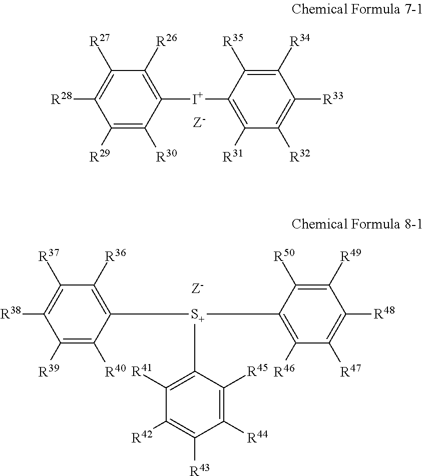
wherein, in Chemical Formula 7-1 and Chemical Formula 8-1,
R²⁶ to R⁵⁰ are each independently hydrogen, a halogen, a hydroxy group, an ester group, a substituted or unsubstituted C1 to C20 alkyl group, a substituted or unsubstituted C1 to C20 alkoxy group, a substituted or unsubstituted C6 to C30 aryl group, or a combination thereof, and
Z⁻ is an anion derived from a conjugate base of inorganic acid or a conjugate base of organic sulfonic acid.

15. The resist topcoat composition as claimed in claim 13, wherein:
Z⁻ is selected from PF₆⁻, BF₄⁻, SbF₆⁻, and an organic sulfonic acid anion.

16. The resist topcoat composition as claimed in claim 15, wherein:
the organic sulfonic acid anion is represented by Chemical Formula 9: 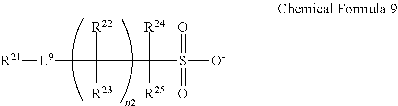
wherein, in Chemical Formula 9,
R²¹ is hydrogen, fluoro, a substituted or unsubstituted C1 to C20 alkyl group, a substituted or unsubstituted C2 to C20 aliphatic unsaturated organic group including one or more double bonds or triple bonds, a cyclic organic group, or a combination thereof,
L⁹ is a single bond, O, S, OC(═O), a substituted or unsubstituted C1 to C20 alkylene group, a substituted or unsubstituted C6 to C20 arylene group, or a combination thereof,
R²² to R²³ are each independently hydrogen, fluoro, a substituted or unsubstituted C1 to C20 alkyl group, a substituted or unsubstituted C3 to C20 cycloalkyl group, a substituted or unsubstituted C2 to C20 aliphatic unsaturated organic group including one or more double bonds or triple bonds, a substituted or unsubstituted C6 to C30 aryl group, or a combination thereof, and
n2 is an integer from 0 to 10.

17. The resist topcoat composition as claimed in claim 1, wherein:
the ionic compound is at least one selected from the compounds listed in Group V:

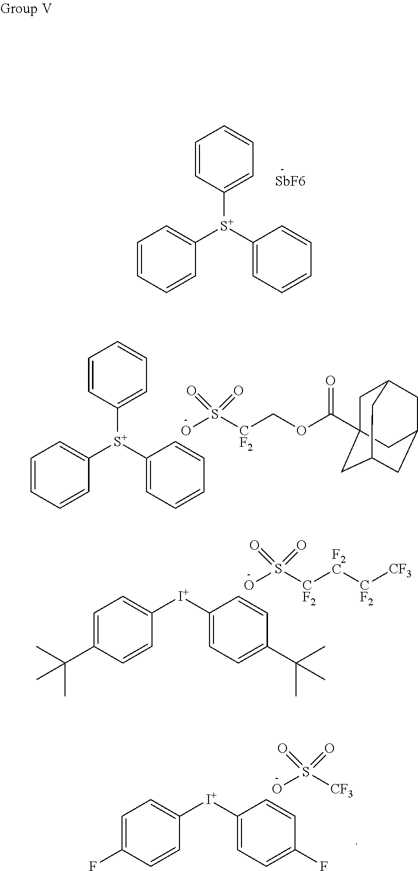

18. The resist topcoat composition as claimed in claim 1, wherein:
the photoacid generator is included in an amount of about 0.1 parts by weight to about 50 parts by weight based on 100 parts by weight of the copolymer.

19. The resist topcoat composition as claimed in claim 1, wherein:
the solvent is an ether-based solvent.

20. A method of forming patterns, comprising:
coating and heating a photoresist composition on a substrate to form a photoresist layer,
coating and heating the resist topcoat composition as claimed in claim 1 on the photoresist layer to form a topcoat, and
exposing and developing the topcoat and the photoresist layer to form a resist pattern.
